(19) United States
(12) Patent Application Publication
(10) Pub. No.: US 2026/0068729 A1
(43) Pub. Date: Mar. 5, 2026

(54) SINTERING OF SEMICONDUCTOR DEVICE ASSEMBLIES USING AN ASSIST FILM

(71) Applicant: SEMICONDUCTOR COMPONENTS INDUSTRIES, LLC, Scottsdale, AZ (US)

(72) Inventors: Yong LIU, Cumberland Foreside, ME (US); Seokbong KIM, Paju-si (KR); Jason Paul GOODELLE, San Jose, CA (US)

(73) Assignee: SEMICONDUCTOR COMPONENTS INDUSTRIES, LLC, Scottsdale, AZ (US)

(21) Appl. No.: 19/314,116

(22) Filed: Aug. 29, 2025

Related U.S. Application Data
(60) Provisional application No. 63/688,934, filed on Aug. 30, 2024.

(51) Int. Cl. H01L 23/00

(52) U.S. Cl. CPC H01L 24/83

(57) ABSTRACT

In a general aspect, a method of sintering a semiconductor device assembly having a surface projection includes applying sintering material to a die attach surface. The method also includes disposing a semiconductor die on the sintering material, the semiconductor die having a surface including a substantially planar portion and at least one projection extending from the substantially planar portion in a direction orthogonal to the surface. The method also includes disposing a film on the surface of the semiconductor die, the film including at least one spacer, where the film is disposed such that the at least one spacer contacts the substantially planar portion. The method also includes applying pressure to the film. The method also includes applying thermal energy at a first sintering temperature to sinter the semiconductor die to the die attach surface. The method also includes removing the film.

### CROSS-REFERENCE TO RELATED APPLICATIONS

This application claims the benefit of U.S. Provisional Application No. 63/688,934, filed on Aug. 30, 2024, which is hereby incorporated by reference in its entirety.

### TECHNICAL FIELD

This description relates to semiconductor devices, and more particularly to techniques for sintering semiconductor devices having a surface projection.

### BACKGROUND

Sintering, such as pressure sintering, can be used to couple (electrically and physically) components of a semiconductor device assembly with one another. For instance, pressure sintering can be used to couple a semiconductor die with a die attach surface and to couple a conductor, such as a conductive clip or signal lead, with a semiconductor die. Pressure applied during such pressure sintering operations can, however, cause cracking in the semiconductor die, such as to material layers used to form an electronic device or circuit on the semiconductor die. For instance, cracking can occur in metal layers, passivation layers, and/or stress reduction buffer layers. Such die cracking can be referred to as die-top cracking and can lead to failure of such an electronic device or circuit.

### SUMMARY

In a general aspect, an apparatus includes a substrate and a semiconductor die sintered to the substrate using an assist film, the semiconductor die having a surface including substantially planar portion and at least one projection extending from the substantially planar portion in a direction orthogonal to the surface. The semiconductor die is sintered to the substrate by disposing the semiconductor die on a sintering material applied to the substrate, disposing the assist film on the surface of the semiconductor die, the assist film including at least one spacer, where the assist film is disposed such that the at least one spacer contacts the substantially planar portion, applying pressure to the assist film, and applying thermal energy at a sintering temperature to sinter the semiconductor die to the substrate.

In some implementations, the at least one spacer defines at least one recess in the film, where the film is disposed such that the at least one projection is disposed within the at least one recess. In some implementations, the at least one spacer defines a pattern of recesses. In some implementations, disposing the film having the at least one spacer includes disposing a plurality of spacers on the surface of the semiconductor die using an adhesive material, the plurality of spacers being disconnected. In some implementations, the at least one projection includes a photosensitive polyimide layer. In some implementations, the film includes at least one of a polymer and a polyimide.

In some implementations, the sintering material is one of a sintering paste or a sintering film. In some implementations, the sintering material is one of a silver sintering material or a copper sintering material. In some implementations, the die attach surface is one of a surface of a die attach paddle of a leadframe and a surface of a metal layer of a direct bonded metal substrate. In some implementations, applying pressure to the film includes applying pressure to the film with a metal plate in a direction orthogonal to the surface of the semiconductor die.

In a general aspect, a method of sintering a semiconductor device assembly having a surface projection includes applying sintering material to a die attach surface. The method also includes disposing a semiconductor die on the sintering material, the semiconductor die having a surface including a substantially planar portion and at least one projection extending from the substantially planar portion in a direction orthogonal to the surface. The method also includes disposing a film on the surface of the semiconductor die, the film including at least one spacer, where the film is disposed such that the at least one spacer contacts the substantially planar portion. The method also includes applying pressure to the film. The method also includes applying thermal energy at a first sintering temperature to sinter the semiconductor die to the die attach surface. The method can also include removing the film.

In some implementations, the at least one spacer defines at least one recess in the film, where the film is disposed such that the at least one projection is disposed within the at least one recess. In some implementations, the at least one spacer defines a pattern of recesses. In some implementations, disposing the film having the at least one spacer includes disposing a plurality of spacers on the surface of the semiconductor die using an adhesive material, the plurality of spacers being disconnected. In some implementations, the at least one projection includes a photosensitive polyimide layer. In some implementations, the film includes at least one of a polymer and a polyimide.

In some implementations, the sintering material is one of a sintering paste or a sintering film. In some implementations, the sintering material is one of a silver sintering material or a copper sintering material. In some implementations, the die attach surface is one of a surface of a die attach paddle of a leadframe and a surface of a metal layer of a direct bonded metal substrate. In some implementations, applying pressure to the film includes applying pressure to the film with a metal plate in a direction orthogonal to the surface of the semiconductor die.

In another general aspect, a method of sintering a semiconductor device assembly having a surface projection includes, a method includes applying sintering material to a die attach surface. The method also includes disposing a semiconductor die on the sintering material, the semiconductor die having a surface including a substantially planar portion and at least one projection extending from the substantially planar portion in a direction orthogonal to the surface. The method also includes disposing a sinter film on the surface of the semiconductor die, the film including at least one spacer extending from the substantially planar portion in a direction orthogonal to the surface. The method also includes disposing a conductor on the sintering film and applying pressure to the conductor. The method also includes applying thermal energy at a first sintering temperature to sinter the conductor to the semiconductor die.

In some implementations, the method also includes disposing the semiconductor die on the sintering material, where the semiconductor die is sintered to the die attach surface contemporaneous with sintering the conductor to the semiconductor die. In some implementations, the at least one projection includes at least one of a portion of a metallization layer and a photosensitive polyimide layer. In some implementations, the conductor is a conductive clip. In some implementations, the sintering film includes at least one of a silver sintering material or a copper sintering material. In some implementations, the sintering material is one of a sintering paste or a sintering film. In some implementations, the die attach surface is one of a surface of a die attach paddle of a leadframe, a surface of a metal layer of a direct bonded metal substrate, or a heat dissipation device.

In another general aspect, a method of sintering a semiconductor device assembly having a surface projection includes applying sintering material to a die attach surface. The method also includes disposing a semiconductor die on the sintering material, the semiconductor die having a surface including a substantially planar portion and at least one projection extending from the substantially planar portion in a direction orthogonal to the surface. The method also includes disposing a film on the surface of the semiconductor die such that the film covers the at least one projection. The method also includes planarizing the film. The method also includes applying pressure to the film. The method also includes applying thermal energy at a first sintering temperature to sinter the semiconductor die to the die attach surface. In some implementations, the film is a photosensitive polyimide layer.

In another general aspect, an apparatus includes a substrate and a semiconductor die coupled to the substrate by a first layer of sintering material, the semiconductor die having a surface including a substantially planar portion and at least one projection extending from the substantially planar portion in a direction orthogonal to the surface. The apparatus also includes a conductor coupled to the surface of the semiconductor die by a second layer of sintering material, the second layer of sintering material including a cavity, the at least one projection being disposed in the cavity.

The details of one or more implementations are set forth in the accompanying drawings and the description below. Other features will be apparent from the description and drawings, and from the claims.

### BRIEF DESCRIPTION OF THE DRAWINGS

FIG. 1A sets forth an example semiconductor device assembly in accordance with at least one embodiment of the present disclosure.

FIG. 1B sets forth an example semiconductor die in accordance with at least one embodiment of the present disclosure.

FIG. 2 sets forth an example sintering tool.

FIGS. 3A-3E set forth an example method of sintering a semiconductor device assembly having a surface projection in accordance with at least one embodiment of the present disclosure.

FIG. 4A sets forth an example assist film for sintering a semiconductor device assembly having a surface projection in accordance with at least one embodiment of the present disclosure.

FIG. 4B sets forth another example assist film for sintering a semiconductor device assembly having a surface projection in accordance with at least one embodiment of the present disclosure.

FIGS. 5A-5F set forth another example method of sintering a semiconductor device assembly having a surface projection in accordance with at least one embodiment of the present disclosure.

FIGS. 6A-6F set forth an example method of sintering a semiconductor device assembly having a surface projection in accordance with at least one embodiment of the present disclosure.

FIGS. 7A-7F set forth an example method of sintering a semiconductor device assembly having a surface projection in accordance with at least one embodiment of the present disclosure.

FIG. 8 sets forth a flow chart of an example method of sintering a semiconductor device assembly having a surface projection in accordance with at least one embodiment of the present disclosure.

FIG. 9 sets forth a flow chart of an example method of sintering a semiconductor device assembly having a surface projection in accordance with at least one embodiment of the present disclosure.

FIG. 10 sets forth a flow chart of an example method of sintering a semiconductor device assembly having a surface projection in accordance with at least one embodiment of the present disclosure.

In the various drawings, which are not necessarily drawn to scale, like reference symbols may indicate like and/or similar components (elements, structures, etc.) in different views and/or different implementations. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are repeated for context and ease of cross reference between related views. Also, not all like elements in the drawings may be specifically referenced with a reference symbol when multiple instances of an element are illustrated.

### DETAILED DESCRIPTION

Semiconductor devices implementing discrete devices, such as power semiconductor devices (transistors, diodes, etc.), or integrated circuits can include active circuitry on a surface of a semiconductor die. That surface can be referred to as an active surface, a top surface, etc. The active surface can have a topology. That is, the active surface can have a surface that is substantially planar and projections that extend from, e.g., above, the surface. Such projections can be metallization stacks that include metal layers, passivation layers, and/or stress reduction buffer layers (e.g., to buffer stress from a molding compound used to encapsulate the semiconductor die). As used herein, substantially planar refers to a surface that is not ideally planar, but is planar within tolerances of an associated manufacturing process. The planarity of such a surface will depend, at least in part, on the particular manufacturing process or processes used.

In pressure sintering processes used to couple (sinter) the semiconductor die with a die attach surface, or to sinter a conductor, such as a conductive clip or signal lead, to the semiconductor die, localized pressure is applied to projections on the active surface. This localized pressure can produce stress on materials included in the projections, such as metal layers, passivation layers, and/or buffer layer. This stress, e.g., in combination with thermal energy applied for sintering, can cause cracking in the projections and/or proximate the projections. As noted above, such cracking can be referred to as die top cracking.

The pressure sintering approaches described herein can reduce or prevent the risk of such die top cracking, as they allow for stress associated with the pressure and/or thermal energy applied during sintering to be more distributed on the semiconductor die. That is, the approaches described herein provide for distributing that stress between a projection or projections, and a substantially planar surface of the semiconductor die from which the projection(s) extend. Such approaches reduce the localized pressure applied to the projection(s), which reduces or prevents the risk of die cracking.

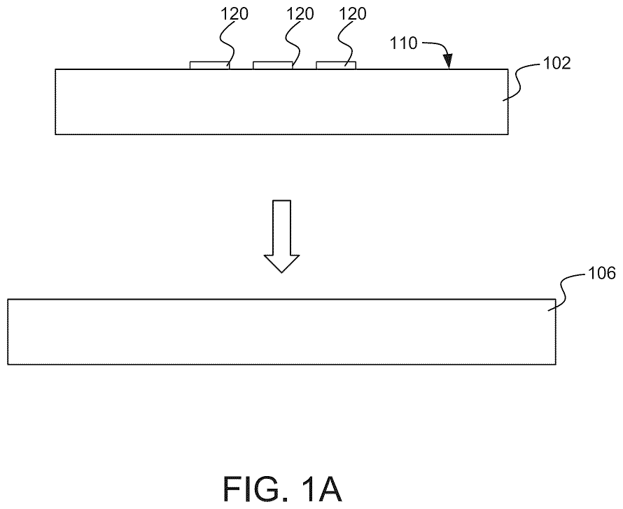

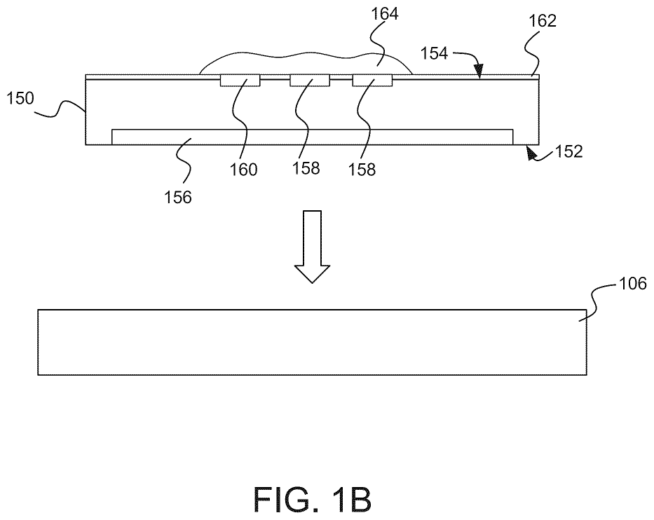

Referring to FIG. 1A, a semiconductor device assembly 102 including one or more projections is shown. For example, the semiconductor device assembly 102 can be a semiconductor die or a semiconductor package assembly that includes a semiconductor die. For example, the semiconductor device assembly 102 can include a semiconductor die at least partially embedded in an epoxy molding compound (EMC). In various examples, the semiconductor die can be fabricated using a silicon substrate, silicon carbide substrate, gallium nitride substrate, a gallium arsenide substrate, or other wide band gap substrates. In some examples, at least a surface of the semiconductor die is exposed through the EMC.

In some examples, the semiconductor device assembly 102 includes at least one layer of metallization proximate to a top surface 110 of the semiconductor device assembly. In various examples, the metallization can include one or more contacts, pads, or elements of a redistribution layer. In some examples, the semiconductor device assembly 102 includes a buffer layer on the top surface 110 of the semiconductor device assembly 102. For example, the buffer layer can include a passivation layer. The passivation layer material can include polyimide, silicon nitride, silicon dioxide, silicon oxynitride, or similar passivation materials. The semiconductor device assembly 102 includes at least one projection 120 extending from the top surface 110 in a direction orthogonal to the top surface 110 of the semiconductor device assembly 102. In various examples, the projection 120 includes at least a portion of the buffer layer, at least a portion of the metallization layer, or a combination of portion of the buffer layer and the metallization layer.

The example of FIG. 1A also includes a die attach surface 106 for receiving the semiconductor device assembly 102. In various examples, the die attach surface 106 can be a substrate such as a ceramic substrate, a dielectric substrate, or a multi-layer substrate. In various examples, a layered substrate can include a direct-bonded metal (DBM) substrate, an active metal brazed substrate (AMB), an aluminum substrate, an insulated metal substrate (IS), a die attach pad (DAP) substrate, and the like. In some implementations, die attach surface 106 is a DBM substrate and can include an insulating layer disposed between a first metal layer (e.g., a top metal layer) and a second metal layer (e.g., a bottom metal layer). The insulating layer can be, for example, a ceramic layer. In some implementations, the insulating layer can be or can include, for example, a ceramic material such as alumina (Al2O3), silicon nitride (Si3N4), or aluminum nitride (AlN)). In some implementations, the DBM substrate can be formed by bonding one or more of the metal layers (e.g., first metal layer, second metal layer) to the insulating layer. In some implementations, one or more of the metal layers can be bonded to the insulating layer using, for example, a high-temperature process (e.g., diffusion bonding). In various examples, the die attach surface 106 can be a surface of a heat dissipation device such as a cooling jacket, heat sink, or other cooling apparatus. In some examples, the die attach surface is a thermal dissipation device and a second thermal dissipation device is thermally coupled to a top side of the semiconductor device assembly 102 to provide double-sided cooling.

In some implementations, the first metal layer and/or the second metal layer of the die attach surface 106 can be or can function as a heat sink. In some implementations, the first metal layer and/or the second metal layer can be coupled to a heat sink. In some implementations, the first metal layer and/or the second metal layer of the die attach surface 106 can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, a DBM substrate can be, or can include, a direct bonded copper (DBC) substrate (e.g., a DBM with copper metal layers). In some implementations, such as in DBC substrate implementations, the first metal layer and/or the second metal layer is a copper layer. In some implementations, where the die attach surface 106 is a DBM substrate, the semiconductor die and DBM substrate can be at least partially encapsulated in a molding compound. In such examples, at least a portion of the bottom metal layer of the DBM substrate can be exposed through the molding compound.

The semiconductor device assembly 102 is configured for sintering to a die attach surface 106. In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature. It will be appreciated that the surface irregularity created by the projections 120 complicates the sintering process.

FIG. 1B illustrates an example of the arrangement in FIG. 1A, where the semiconductor device assembly 102 is a semiconductor die 150. In some examples, the semiconductor die 150 includes a power device. For example, the semiconductor die 150 can include one or more of a metal-oxide-semiconductor field-effect transistor (MOSFET) device, an insulated-gate bipolar transistor (IGBT), an integrated circuit (IC), an inverter, a power conversion circuit, a bridge circuit, fast recovery diode (FRDs), a diode, and/or so forth. In some implementations, the semiconductor die 150 can include a power device for conditioning, converting, or switching a power supply. In various examples, the semiconductor die 150 can be fabricated using a silicon substrate, silicon carbide substrate, gallium nitride substrate, or a gallium arsenide substrate. In a particular example, the semiconductor die 150 is fabricated using and includes a silicon carbide (SiC) material. The semiconductor die 150 includes a bottom surface 152 and a top surface 154. The bottom surface 152 includes a drain contact 156, which may be a continuous metal layer electrically coupled to the drain region of the power device. The top surface 154 may be referred to as the active surface. The top surface 154 includes power device contacts including at least one source contact 158 and at least one gate contact 160. For example, a source contact 158 and a gate contact 160 can be conductive pads or other layers of metallization that are coupled to source metal and gate electrodes, respectively, of the power device. In one example, the semiconductor die 150 includes a vertical trench MOSFET device.

In the example of FIG. 1B, a passivation layer 162 is applied to portions of the top surface 154 of the semiconductor die 150, thus creating a substantially planar surface. The passivation layer 162 can be applied by, for example, spin coating, spray coating, chemical vapor deposition, physical vapor deposition, lamination, and other processes that will be appreciated by those of skill in the art. For example, the passivation layer material can include polyimide, silicon nitride, silicon dioxide, or silicon oxynitride. The top surface 154 of the semiconductor die 150 also includes photosensitive polyimide (PSPI) bumps 164 that correspond to the projections 120 in FIG. 1A. The PSPI bumps 164 can correspond to the locations of the device contacts such as source contact 158 and gate contact 160. In some examples, a PSPI layer is deposited at least over the top surface 154 of the semiconductor die 150 by, for example, spin-coating to achieve a thickness in the range of 5-20 μm. The PSPI layer is subsequently patterned using a photolithographic process to create the PSPI bumps 164 at locations corresponding to the exposed metallization layers such as source contacts 158 and gate contacts 160, providing a layer of protection for the device contacts. Eventually, the PSPI bumps 164 can be partially removed by etching with an opening for connecting wire bonds and/or a conductive clip to the semiconductor die, or the PSPI bumps 164 can be made with an opening for source and gate contact pads. The PSPI bumps 164 extend from the substantially planar surface provided by the passivation layer 162. For example, a difference between the thickness of the passivation layer 162 and the thickness of the PSPI bumps, extending upward from the top surface 154, can be greater than 5 μm. The semiconductor die 150 is configured for sintering to the die attach surface 106, described above. It will be appreciated that, as mentioned above, the surface irregularity created by the PSPI bumps 164 complicates the sintering process.

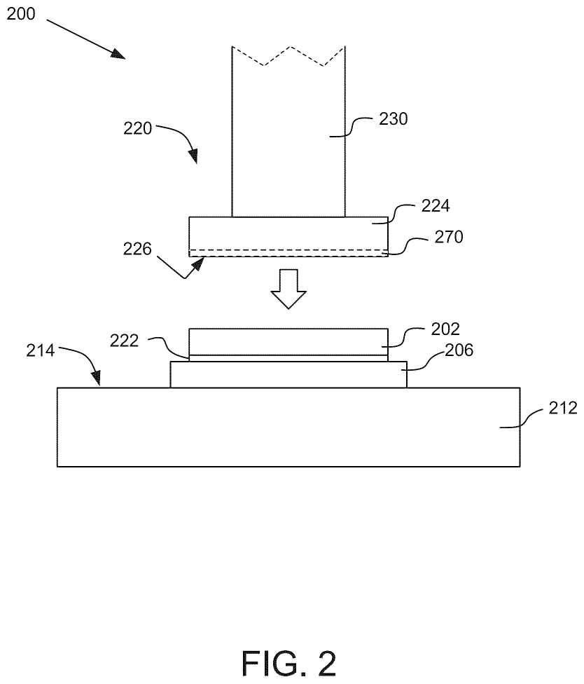

Referring to FIG. 2, an example sintering tool 200 configured for attaching a semiconductor die 202 to a die attach surface 206, or a conductor to a semiconductor die surface, is shown. The example sintering tool 200 includes a heated lower platen 212 that defines a planar support surface 214 for receiving the die attach surface 206. In some implementations, the lower platen 212 incorporates embedded heating elements and temperature sensors to maintain a predetermined bonding temperature profile during sintering.

A bonding head assembly 220 is positioned above the lower platen 212 and includes a bonding press 224 having a contact surface 226 (e.g., a metal plate or a metal plate and compliant layer) for engaging the die 202. The bonding press 224 may be formed of a thermally conductive material and can, in some implementations, include an embedded heater for localized heating of the die 202. The bonding head assembly 220 is coupled to a force application mechanism 230, such as a pneumatic cylinder, configured to apply a controlled bonding force at the die attach interface. In some embodiments, the contact surface 226 includes a compliant layer 270 formed from a thermally stable, low-adhesion polymer to prevent scratching and distribute load evenly.

In operation, a bonding material 222, such as sintering paste or sintering film, is applied to the die attach surface 206 on the support surface 214. The die 202 is positioned on the bonding material 222 and the bonding press 224 is brought into contact with the bonding material 222, and bonded under controlled temperature and pressure. The result is a metallurgically bonded interface between the die 202 and die attach surface 206 with high thermal conductivity and mechanical strength suitable for high-power semiconductor applications.

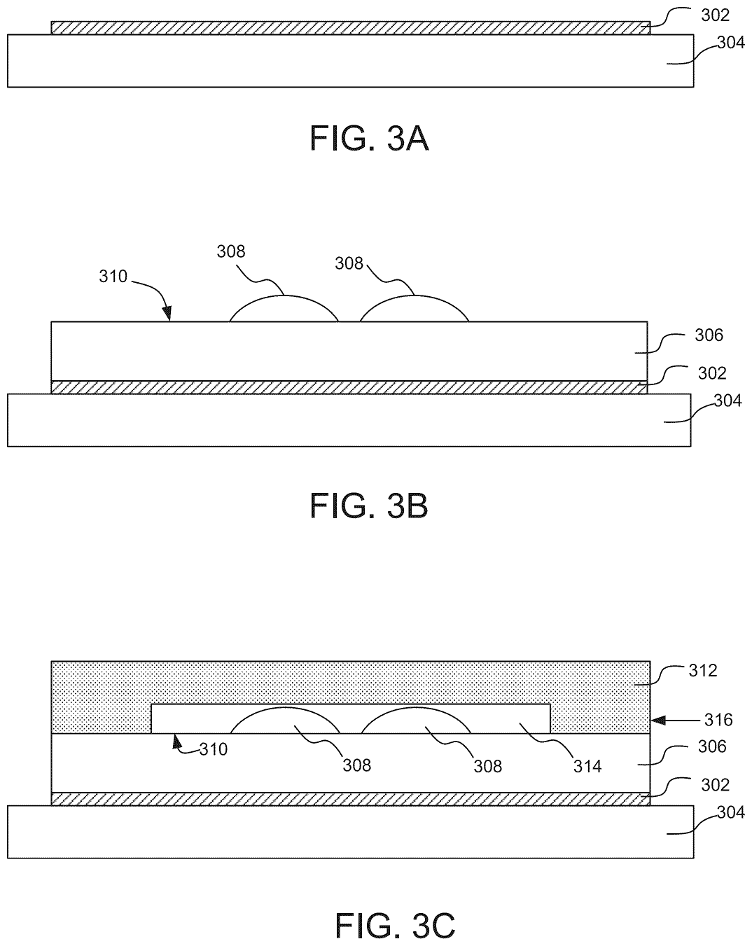

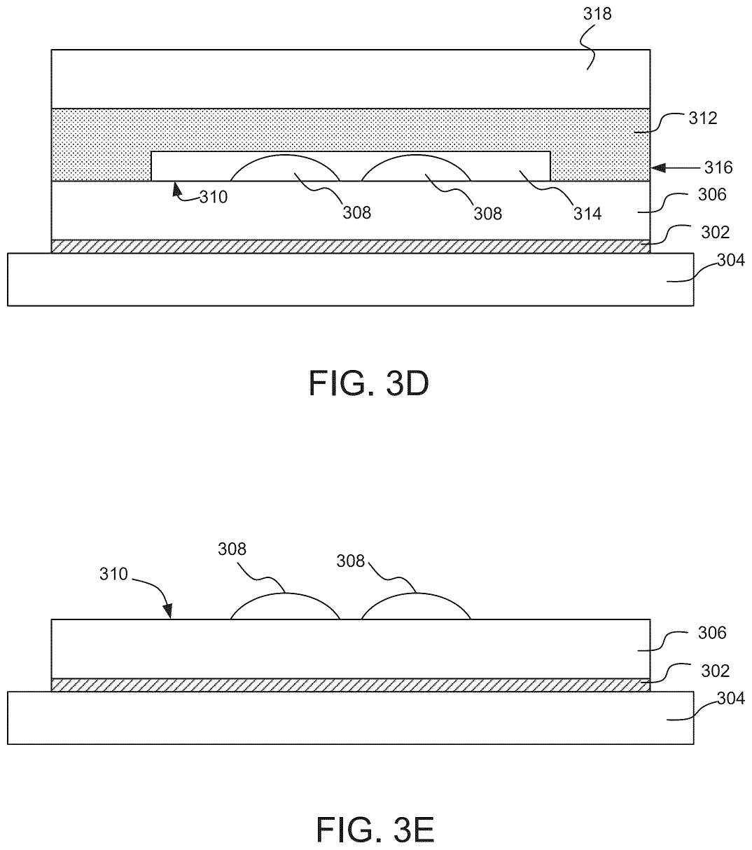

FIGS. 3A to 3E illustrate a process of fabricating a semiconductor device assembly in accordance with at least one embodiment of the present disclosure. Beginning with FIG. 3A, a sintering material 302 is disposed on a die attach surface 304. In some implementations, the sintering material is a sintering paste. In other implementations, the sintering material is a sintering film, such as a sintering film preform. In some implementations, the sintering material can be a silver (Ag) sintering material. In other implementations, the sintering material can be a copper (Cu) sintering material, or other sintering material. In some implementations, the die attach surface 304 is a die attach paddle of a leadframe. In other implementations, the die attach surface 304 is a substrate such as a DBM substrate. The die attach surface 304 can include some or all of the features of the die attach surface 106 in FIGS. 1A and 1B.

As shown in FIG. 3B, a semiconductor die 306 is disposed on the sintering material 302. For example, the semiconductor die can include some or all of the components of the semiconductor device assembly 102 of FIG. 1A or the semiconductor die 150 of FIG. 1B. The semiconductor die 306 includes a projection 308 that extends from a substantially planar surface 310 of an active surface of the semiconductor die 306. In this example, the projection 308 can include a metal layer, passivation layer, and/or buffer layer stack, where the metal layer can define a metal bump and/or form electrical traces, e.g., a gate runner, of the active circuitry of the semiconductor die. In some implementations, the projection 308 includes a photosensitive polyimide bump. Two projections 308 are shown in FIGS. 3B to 3E for purpose of illustration. However, it will be appreciated that a semiconductor die 306 can include any number and arrangement of such projections. Further, while the projections are shown as rounded bumps, the projections can include elongated structures or more complex shapes, having a rounded, beveled, or planar top surface.

In FIG. 3C, a film 312 is applied to the surface 310 of the semiconductor die 306 such that the projection 308 is disposed in a recess 314 in the film 312. The recess 314 can include, for example, one or more depressions, cavities, slots, wells, indentions, and/or grooves. The film 312, which can be referred to as an assist film, includes extended spacers 316 (e.g., legs, feet, struts, beams, walls, pillars, etc.) that are adjacent to and define, at least in part, the recess 314 in which the projection 308 is disposed. As shown in FIG. 3C, in this example, the spacers 316 contact the substantially planar surface 310 of the semiconductor die 306. Depending on a particular implementation, the film 312 can be formed from polyimide, PSPI, polymers such as polytetrafluoroethylene (PTFE), or other materials suitable for high temperature applications. In some implementations, the film 312 is deformable and/or can have some elasticity (resiliency), which can allow for absorbing a portion of the pressure applied during a pressure sintering operation. FIG. 3C illustrates a film with a single recess 314 for purposes of illustration and by way of example. In some implementations, the film 312 can include a plurality of recesses, such as a matrix, pattern, etc. of recesses.

In FIG. 3D, a sintering tool 318 (e.g., sintering tool 200 of FIG. 2) including a pressure plate, a metal plate, a block, etc., is disposed on (in contact with) the film 312. In this example, the sintering tool 318 is used to apply pressure to the surface 310, which in turn applies pressure to the semiconductor die 306 against the die attach surface 304. This pressure can be applied in a direction that is towards, and orthogonal to the semiconductor die 306, e.g., to a plane of the semiconductor die 306. As the film 312 contacts the substantially planar surface 310 of the semiconductor die 306, pressure applied by the sintering tool 318 is distributed across the active surface of the semiconductor die 306, which reduces localized stress on the projections as compared to prior implementations. Accordingly, the approach illustrated in FIG. 3D can reduce or prevent the risk of die top cracking during pressure sintering operations. While applying pressure with the sintering tool 318, the assembly of FIG. 3D is heated to a sintering temperature to couple (sinter) the semiconductor die to the die attach surface.

In FIG. 3E, after the pressure sintering is completed, the sintering tool 318 and the film 312 are removed, producing a semiconductor die 306 that is sintered to the die attach surface 304. In various implementations, the film 312 can be removed mechanically or by a chemical bath. For example, the adhesion between the film 312 and the semiconductor die 306 can be low, such that the film 312 can be mechanically peeled off the semiconductor die 306 by raising the temperature of the film 312 to its glass transient temperature. Accordingly, subsequent processing can be performed. For example, PSPI bumps can be removed to allow for the attachment of wire bonds or other conductive structures to exposed metallization layers on the active surface of the semiconductor die 306. Conductive structures forming an electrical connection to the semiconductor die 306 can include materials such a gold, silver, aluminum, copper, or combinations of such materials.

In an alternative implementation, instead of applying the film 312 to the semiconductor die 306, the film 312 can be coupled to the sintering tool 318. For example, the film 312 can be coupled to a metal plate defining a contact surface of a bonding press (e.g., bonding press 224 in FIG. 2) using an adhesive material. In one example, the film 312 can correspond to the compliant layer 270 of FIG. 2.

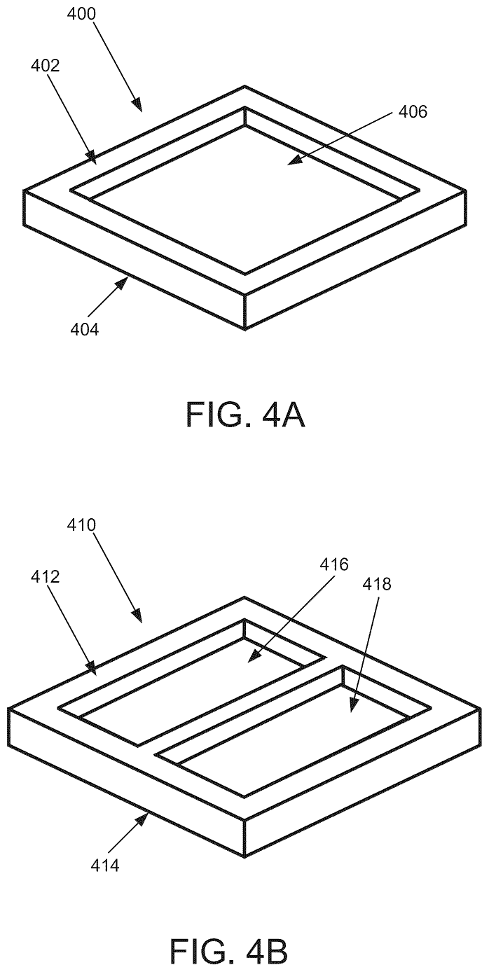

FIGS. 4A and 4B illustrate example implementations of an assist film such as film 312 described above. Relative to FIG. 3C, the assist films 400 and 410 shown in FIGS. 4A and 4B are shown bottom side up. The assist film 400 of FIG. 4A includes a spacer 402 (such as spacer 316 in FIGS. 3C) extending from a base portion 404. The base portion 404 and the spacers 402 define a recess 406 (such as recess 314 in FIG. 3C). The assist film 410 in FIG. 4B includes a spacer 412 (such as spacer 316 in FIGS. 3C) extending from a base portion 414. The base portion 414 and the spacers 412 define a recesses 416, 418 (such as recess 314 in FIG. 3C). It will be appreciated that various patterns of spacers (e.g., walls, beams, feet, pillars, spacers, etc.) can define various patterns of recesses (e.g., cavities, channels, slots, grooves, etc.). The recesses 406, 416, 418 can be formed by, for example, a direct laser process such as laser ablation or laser texturing, chemical etching, or plasma etching a layer of material to remove material from the film.

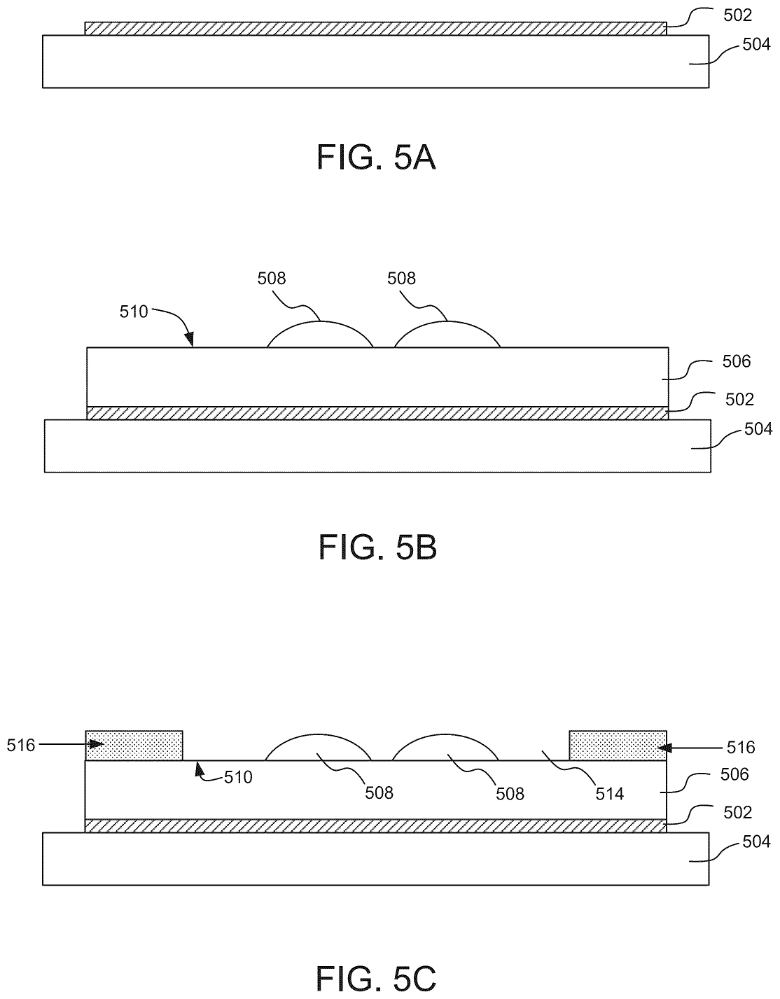

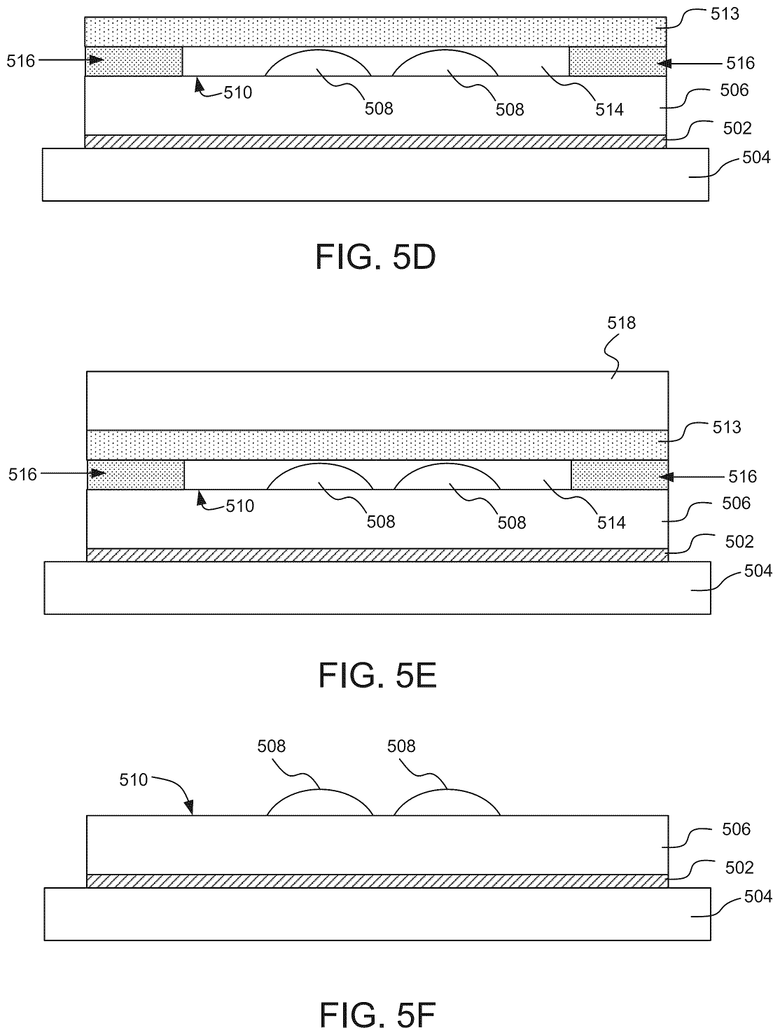

FIGS. 5A to 5F illustrate a process of fabricating a semiconductor device assembly in accordance with at least one embodiment of the present disclosure. Beginning with FIG. 5A, a sintering material 502 is disposed on a die attach surface 504. In some implementations, the sintering material is a sintering paste. In other implementations, the sintering material is a sintering film, such as a sintering film preform. In some implementations, the sintering material can be a silver (Ag) sintering material. In other implementations, the sintering material can be a copper (Cu) sintering material, or other sintering material. In some implementations, the die attach surface 504 is a die attach paddle of a leadframe. In other implementations, the die attach surface 504 is a substrate such as a DBM substrate. The die attach surface 504 can include some or all of the features of the die attach surface 106 in FIGS. 1A and 1B.

As shown in FIG. 5B, a semiconductor die 506 is disposed on the sintering material 502. For example, the semiconductor die can include some or all of the components of the semiconductor device assembly 102 of FIG. 1A or the semiconductor die 150 of FIG. 1B. The semiconductor die 506 includes a projection 508 that extends from a substantially planar surface 510 of an active surface of the semiconductor die 506. In this example, the projection 508 can include a metal layer, passivation layer, and/or buffer layer stack, where the metal layer can define a metal bump and/or form electrical traces, e.g., a gate runner, of the active circuitry of the semiconductor die. In some implementations, the projection 508 includes a photosensitive polyimide bump. Two projections 508 are shown in FIGS. 5B to 5F for purpose of illustration. However, it will be appreciated that a semiconductor die 506 can include any number and arrangement of such projections. Further, while the projections are shown as rounded bumps, the projections can include elongated structures or more complex shapes, having a rounded, beveled, or planar top surface.

In FIG. 5C, a film composed of one or more spacers 516 is applied to the surface 510 of the semiconductor die 506. In various implementations, the spacers 516 can be feet, beams, walls, spacers, pillars, and so forth. As shown in the example of FIG. 5C, the spacers 516 contact the substantially planar surface 510 of the semiconductor die 506. Depending on a particular implementation, the spacers can be formed from a polyimide, PSPI, polymer (e.g., PTFE), or other material suitable for high temperature applications. In some implementations, the spacer 516 are deformable and/or can have some elasticity (resiliency), which can allow for absorbing a portion of the pressure applied during a pressure sintering operation. In some implementations, the spacers 516 are coupled to the planar surface 510 via an adhesive material. In some implementations, as shown in FIG. 5D, an assist film 513 is applied to the spacers 516. The assist film 513 can be the same material as the spacers 516 or a different material. For example, the assist film can be a polymer, a polyimide, or other material suitable for high temperature applications. It will be appreciated that the step shown in FIG. 5D can be omitted in some implementations.

In FIG. 5E, a sintering tool 518 (e.g., sintering tool 200 of FIG. 2) including a pressure plate, a metal plate, a block, etc., is disposed on (in contact with) the spacers 516 or the assist film 513, depending on the implementation. When another object, such as the sintering tool 518 or the assist film 513, is placed in contact with the spacers 516, the spacers 516 define, at least in part, a recess 514 in which the projection 508 is disposed. FIG. 5E illustrates a single recess 514 for purposes of illustration and by way of example. In some implementations, the spacers 516 and sintering tool 518 or assist film 513 can define a plurality of recesses, such as a matrix, pattern, etc. of recesses.

In this example, the sintering tool 518 is used to apply pressure to the spacers 516 (and the second assist film 513, if present), which in turn applies pressure to the semiconductor die 506, e.g., against the die attach surface 504. This pressure can be applied in a direction that is towards, and orthogonal to the semiconductor die 506, e.g., to a plane of the semiconductor die 506. As the spacers 516 contact the substantially planar surface 510 of the semiconductor die 506, pressure applied by the sintering tool 518 is distributed across the active surface of the semiconductor die 506, which reduces localized stress on the projections as compared to prior implementations. Accordingly, the approach illustrated in FIG. 5E can reduce or prevent the risk of die top cracking during pressure sintering operations. While applying pressure with the sintering tool 518, the assembly of FIG. 5E is heated to a sintering temperature to couple (sinter) the semiconductor die to the die attach surface.

In FIG. 5F, after the pressure sintering is completed, the sintering tool 518 and the spacers 516 (and film 513, when present) are removed, producing a semiconductor die 506 that is sintered to the die attach surface 504. In various implementations, the spacers 516 and/or the film 513 can be removed mechanically or by a chemical bath. For example, the adhesion between the spacers 516 and the semiconductor die 506 can be low, such that the spacers 516 can be mechanically peeled off the semiconductor die 506 by raising the temperature of the spacers 516 to their glass transient temperature. Accordingly, subsequent processing can be performed. For example, PSPI bumps can be removed to allow for the attachment of wire bonds or other conductive structures to exposed metallization layers on the active surface of the semiconductor die 506.

In an alternative implementation, instead of coupling the spacers 516 to the semiconductor die 506, the spacers 516 can be coupled to the sintering tool 518. For example, the spacers 516 can be coupled to a metal plate defining a contact surface of a bonding press (e.g., bonding press 224 in FIG. 2) using an adhesive material. In one example, the spacers 516 can correspond to the compliant layer 270 of FIG. 2.

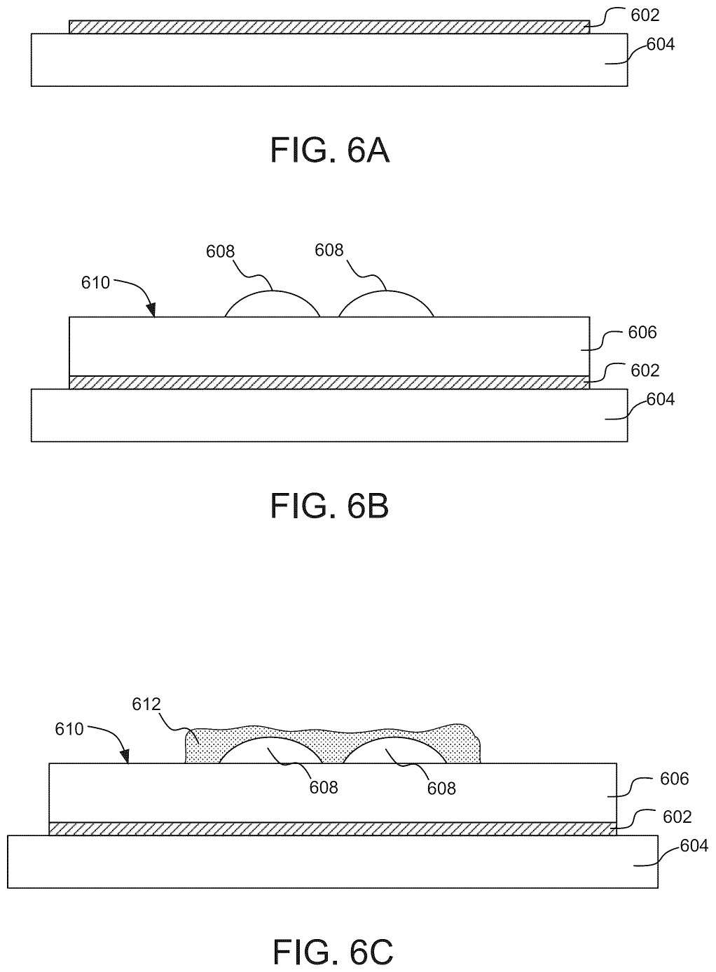

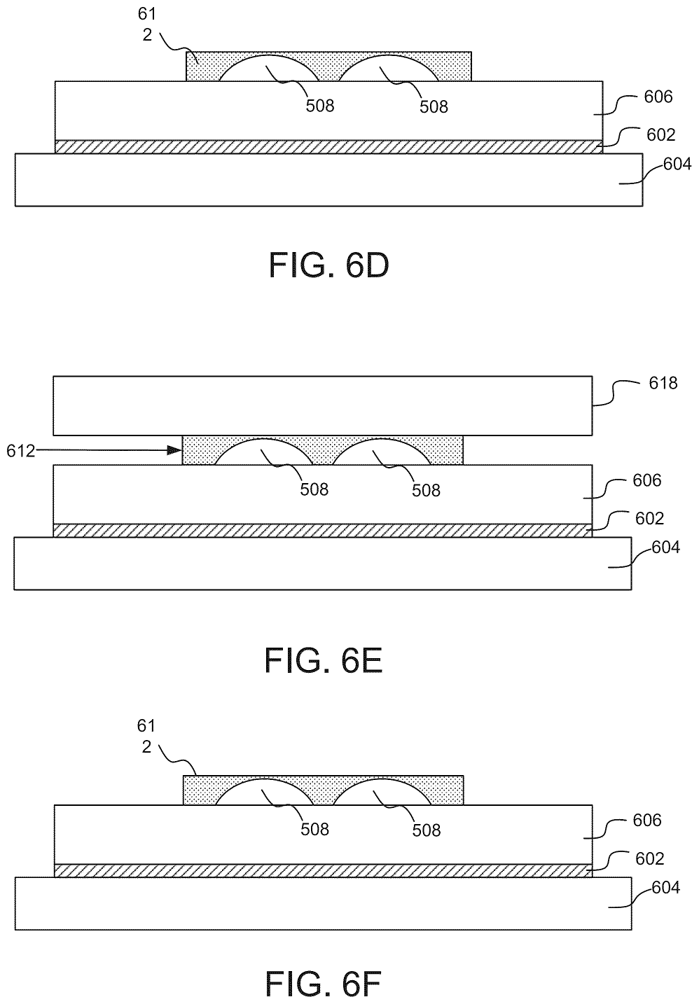

FIGS. 6A to 6E illustrate a process of fabricating a semiconductor device assembly in accordance with at least one embodiment of the present disclosure. Beginning with FIG. 6A, a sintering material 602 is disposed on a die attach surface 604. In some implementations, the sintering material is a sintering paste. In other implementations, the sintering material is a sintering film, such as a sintering film preform. In some implementations, the sintering material can be a silver (Ag) sintering material. In other implementations, the sintering material can be a copper (Cu) sintering material, or other sintering material. In some implementations, the die attach surface 604 is a die attach paddle of a leadframe. In other implementations, the die attach surface 604 is a substrate such as a DBM substrate. The die attach surface 604 can include some or all of the features of the die attach surface 106 in FIGS. 1A and 1B.

As shown in FIG. 6B, a semiconductor die 606 is disposed on the sintering material 602. For example, the semiconductor die can include some or all of the components of the semiconductor device assembly 102 of FIG. 1A or the semiconductor die 150 of FIG. 1B. The semiconductor die 606 includes a projection 608 that extends from a substantially planar surface 610 of an active surface of the semiconductor die 606. In this example, the projection 608 can include a metal layer, passivation layer, and/or buffer layer stack, where the metal layer can define a metal bump and/or form electrical traces, e.g., a gate runner, of the active circuitry of the semiconductor die. In some implementations, the projection 608 includes a photosensitive polyimide bump. Only a single projection 608 is shown in FIGS. 6B to 6E for purpose of illustration. However, it will be appreciated that a semiconductor die 606 can include any number and arrangement of such projections. Further, while the projections are shown as rounded bumps, the projections can include elongated structures or more complex shapes, having a rounded, beveled, or planar top surface.

In FIG. 6C, a film 612 is applied to the surface 610 of the semiconductor die 606 such that the projection 608 is covered by the film 612. Depending on a particular implementation, the film 612 can be formed from polyimide, PSPI, PTFE or other polymer, or other material suitable for high temperature applications. In some implementations, the film 612 is deformable and/or can have some elasticity (resiliency), which can allow for absorbing a portion of the pressure applied during a pressure sintering operation. As shown in FIG. 6D, the film 612 is planarized. In some implementations, the film 612 is planarized by etching and/or laser flattening. In some implementations, the film 612 is planarized by increasing the temperature of the film and applying pressure via a stamp or plate to flatten the surface of the film. For example, this can be performed using a sintering tool before, or as part of, sintering the semiconductor die 606 to the die attach surface. In some implementations, the film 612 is applied by spin coating the lower area around the projection 608 to achieve a flat surface around and/or above the projection 608.

In FIG. 6E, a sintering tool 618 (e.g., sintering tool 200 of FIG. 2) including a pressure plate, a metal plate, a block, etc., is disposed on (in contact with) the film 612. In this example, the sintering tool 618 is used to apply pressure to the film 612, which in turn applies pressure to the semiconductor die 606, e.g., against the die attach surface 604. This pressure can be applied in a direction that is towards, and orthogonal to the semiconductor die 150, e.g., to a plane of the semiconductor die 150. As the film 612 contacts the substantially planar surface 610 of the semiconductor die 606, pressure applied by the sintering tool 618 is distributed across the active surface of the semiconductor die 606, which reduces localized stress on the projections as compared to prior implementations. Accordingly, the approach illustrated in FIG. 6E can reduce or prevent the risk of die top cracking during pressure sintering operations. While applying pressure with the sintering tool 618, the assembly of FIG. 6E is heated to a sintering temperature to couple (sinter) the semiconductor die to the die attach surface.

In FIG. 6F, after the pressure sintering is completed, the process concludes by removing the sintering tool 618, resulting in the semiconductor die 606 being sintered to the die attach surface 704. Accordingly, subsequent processing can be performed. For example, PSPI bumps can be removed to allow for the attachment of wire bonds or other conductive structures to exposed metallization layers on the active surface of the semiconductor die 606.

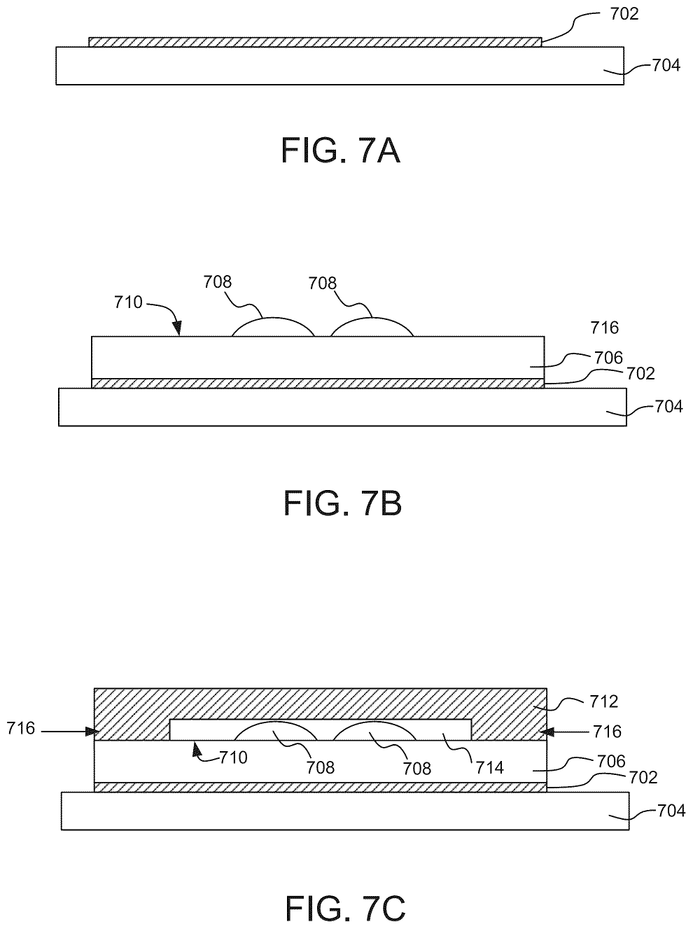

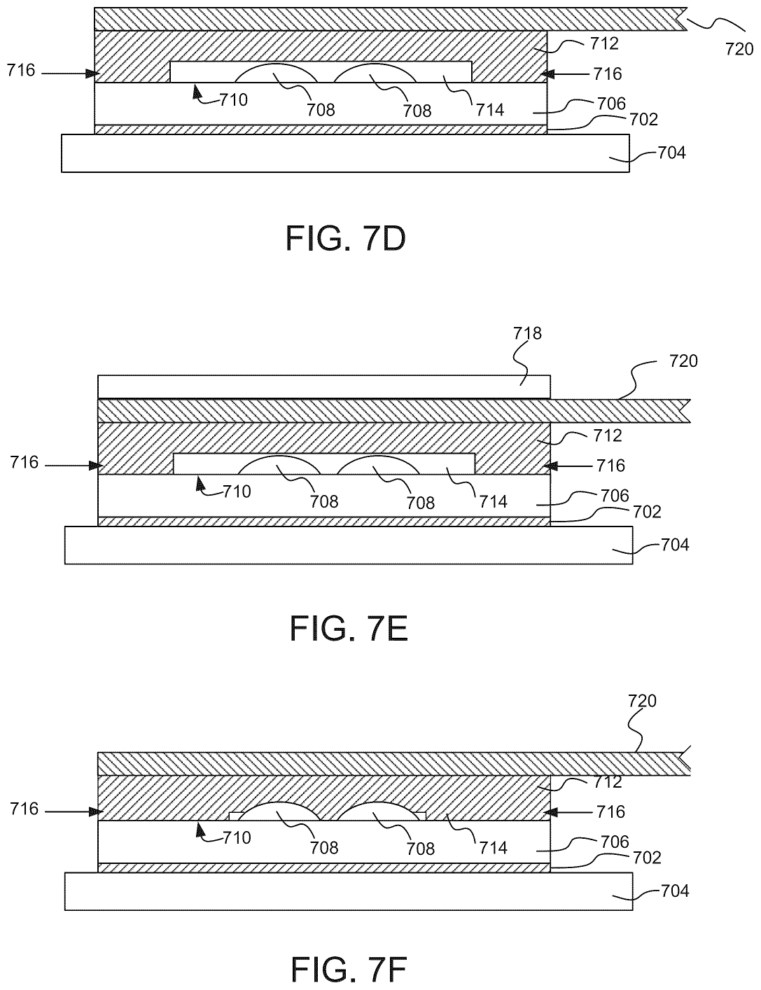

FIGS. 7A to 7E illustrate a process of fabricating a semiconductor device assembly in using enhanced sintering techniques accordance with at least one embodiment of the present disclosure. Beginning with FIG. 7A, a sintering material 702 is disposed on a die attach surface 704. In some implementations, the sintering material is a sintering paste. In other implementations, the sintering material is a sintering film, such as a sintering film preform. In some implementations, the sintering material can be a silver (Ag) sintering material. In other implementations, the sintering material can be a copper (Cu) sintering material, or other sintering material. In some implementations, the die attach surface 704 is a die attach paddle of a leadframe. In other implementations, the die attach surface 704 is a substrate such as a DBM substrate. The die attach surface 704 can include some or all of the features of the die attach surface 106 in FIGS. 1A and 1B.

As shown in FIG. 7B, a semiconductor die 706 is disposed on the sintering material 702. For example, the semiconductor die can include some or all of the components of the semiconductor device assembly 102 of FIG. 1A or the semiconductor die 150 of FIG. 1B. The semiconductor die 706 includes a projection 708 that extends from a substantially planar surface 710 of an active surface of the semiconductor die 706. In this example, the projection 708 can include a metal layer, passivation layer, and/or buffer layer stack, where the metal layer can define a metal bump and/or form electrical traces, e.g., a gate runner, of the active circuitry of the semiconductor die. In some implementations, the projection 708 includes a photosensitive polyimide bump. Two projections 708 are shown in FIGS. 7B to 7E for purpose of illustration. However, it will be appreciated that a semiconductor die 706 can include any number and arrangement of such projections. Further, while the projections are shown as rounded bumps, the projections can include elongated structures or more complex shapes, having a rounded, beveled, or planar top surface.

In FIG. 7C, a sintering film 712 is applied to the surface 710 of the semiconductor die 706 such that the projection 708 is disposed in a recess 714 in the sintering film 712. The recess 314 can include, for example, one or more depressions, cavities, slots, wells, indentions, and/or grooves. The sintering film 712 includes extended spacers 716 (e.g., legs, feet, struts, beams, walls, pillars, etc.) that are adjacent to and define, at least in part, the recess 714 in which the projection 708 is disposed. As shown in the example of FIG. 3C, the spacers 716 contact the substantially planar surface 710 of the semiconductor die 706. The one or more recesses 714 in the sintering film 712 can be formed by, for example, laser ablation or mechanically stamping the sintering film 712. FIG. 3C illustrates a film with a single recess 714 for purposes of illustration and by way of example. However, in some implementations, the sintering film 712 can include a plurality of recesses, such as a matrix, pattern, etc. of recesses. Depending on a particular implementation, the sintering film 712 is a preformed film of silver, copper, or other sintering material.

As shown in FIG. 7D, a conductor 720 is disposed on the sintering film 712. The conductor can be, for example, a conductive clip that is also configured for attachment to a leadframe or a conductive pad on a substrate. In some examples, the conductive clip is sintered to a leadframe or a substrate at the same time the conductive clip is sintered to the semiconductor die 706. In some implementations, at least one projection includes an exposed metal contact that is to be sintered to the conductor 720

In FIG. 7E, a sintering tool 718 (e.g., sintering tool 200 of FIG. 2) including a pressure plate, a metal plate, a block, etc., is disposed on (in contact with) the conductor 720. In this example, the sintering tool 718 is used to apply pressure to the conductor 720, which in turn applies pressure to the semiconductor die 706 against the die attach surface 704. This pressure can be applied in a direction that is towards, and orthogonal to the semiconductor die 706, e.g., to a plane of the semiconductor die 706. As the sintering film 712 contacts the substantially planar surface 710 of the semiconductor die 706, pressure applied by the sintering tool 718 is distributed across the active surface of the semiconductor die 706, which reduces localized stress on the projection 708 as compared to prior implementations. Accordingly, the approach illustrated in FIG. 7D can reduce or prevent the risk of die top cracking during pressure sintering operations. While applying pressure with the sintering tool 718, the assembly of FIG. 7E is heated to a sintering temperature to sinter the semiconductor die 706 to the die attach surface 704 at the same time the conductor 720 is sintered to the semiconductor die 706.

In FIG. 7F, after the pressure sintering is completed, the process concludes by removing the sintering tool 718, resulting in the conductor 720 being sintered to the semiconductor die 706 and the semiconductor die 706 being sintered to the die attach surface 704.

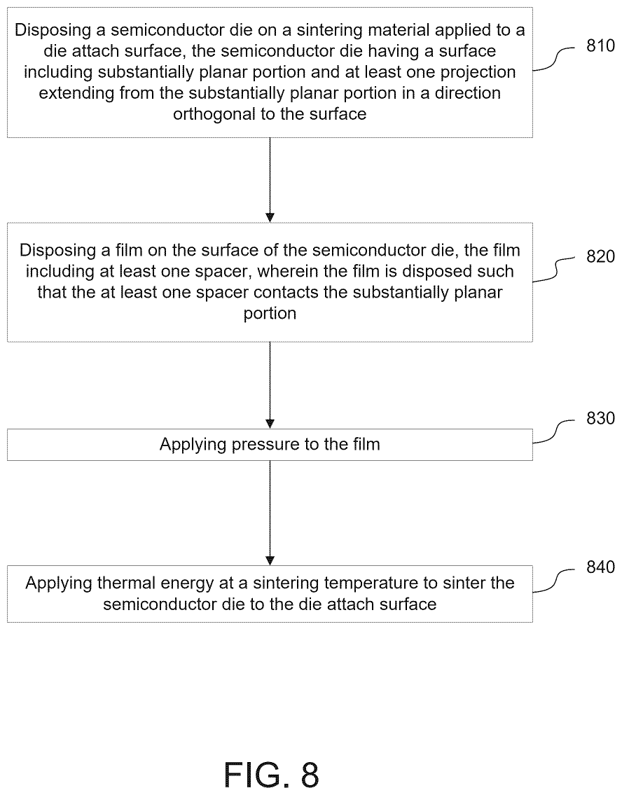

FIG. 8 sets forth an example method of sintering a semiconductor device assembly having a surface projection in accordance with at least one embodiment. For example, the method of FIG. 8 can implement the processes shown in FIGS. 3A-3E and 5A-5F. The method includes disposing 810 a semiconductor die on a sintering material applied to a die attach surface, the semiconductor die having a surface including substantially planar portion and at least one projection extending from the substantially planar portion in a direction orthogonal to the surface. The method also includes disposing 820 a film on the surface of the semiconductor die, the film including at least one spacer, where the film is disposed such that the at least one spacer contacts the substantially planar portion. The method also includes applying 830 pressure to the film. The method also includes applying 840 thermal energy at a sintering temperature to sinter the semiconductor die to the die attach surface.

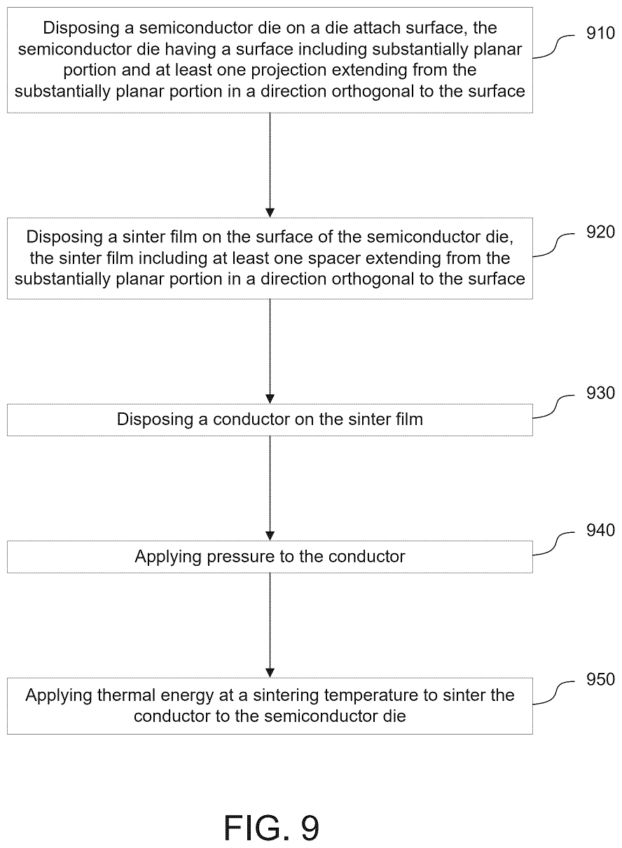

FIG. 9 sets forth an example method of sintering a semiconductor device assembly having a surface projection in accordance with at least one embodiment. For example, the method of FIG. 9 can implement the processes shown in FIGS. 6A-6F. The method includes disposing 910 a semiconductor die on a die attach surface, the semiconductor die having a surface including substantially planar portion and at least one projection extending from the substantially planar portion in a direction orthogonal to the surface. The method also includes disposing 920 a sinter film on the surface of the semiconductor die, the sinter film including at least one spacer extending from the substantially planar portion in a direction orthogonal to the surface. The method also includes disposing 930 a conductor on the sinter film. The method also includes applying 940 pressure to the conductor. The method also includes applying 950 thermal energy at a sintering temperature to sinter the conductor to the semiconductor die.

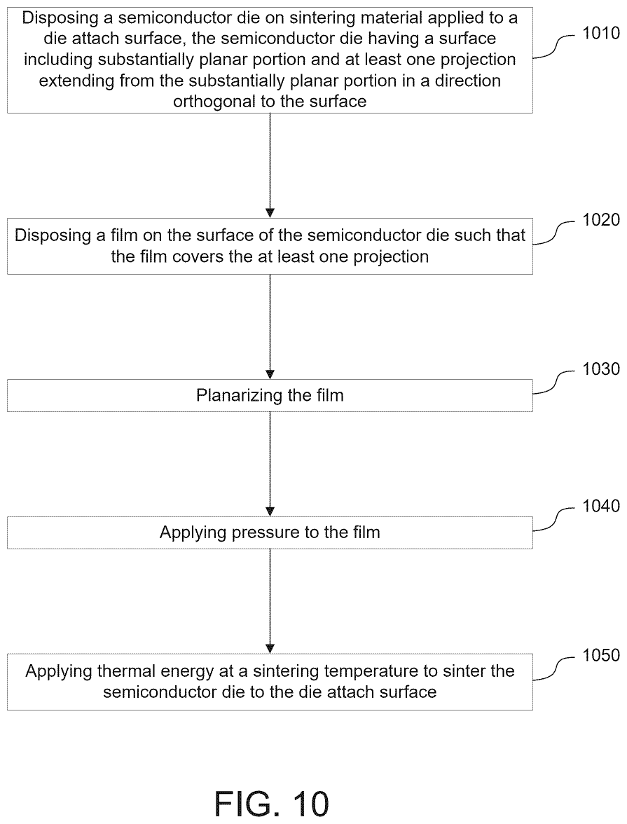

FIG. 10 sets forth an example method of sintering a semiconductor device assembly having a surface projection in accordance with at least one embodiment. For example, the method of FIG. 10 can implement the processes shown in FIGS. 7A-7F. The method includes disposing 1010 a semiconductor die on sintering material applied to a die attach surface, the semiconductor die having a surface including substantially planar portion and at least one projection extending from the substantially planar portion in a direction orthogonal to the surface. The method also includes disposing 1020 a film on the surface of the semiconductor die such that the film covers the at least one projection. The method also includes 1030 planarizing the film. The method also includes applying 1040 pressure to the film. The method also includes applying 1050 thermal energy at a sintering temperature to sinter the semiconductor die to the die attach surface.

In some implementations, soldering can be, or can include, a process of joining two surfaces (e.g., metal surfaces) together using a molten filler metal (e.g., Tin (Sn), Lead (Pb), Silver (Ag), Copper (Cu), or metal alloys that include combinations of these metals) that can be referred to as a solder. In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature. In some implementations, one or more of the components described herein can be coupled using materials such as, for example, a solder, a sintering (e.g., silver, copper) material, and/or other metal-to-metal type bonding materials. In some implementations, a coupling of components can be performed using, for example, a solder process, a sintering process (e.g., a silver sintering process, a copper sintering process), and/or other metal-to-metal type bonding processes. In some examples, a die surface or die attach surface (e.g., a substrate, heat sink, leadframe, etc.) is conditioned to promote a strong metallurgical bond. For example, portions of the die or die attach surface can be metallized with an adhesion layer (e.g., titanium, titanium-tungsten, or chromium), and/or a barrier layer (e.g., nickel, platinum, tungsten, or molybdenum and/or a finish layer (e.g., silver or copper plating).

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wirebonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package. In some implementations, one or more portions of a leadframe can be coupled to a pad (e.g., a bond pad) on at least a portion of a DBM substrate.

The semiconductor device packages described herein can include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

In some implementations, a molding compound (e.g., molding material or compound, an encapsulation material) can be or can include a non-conducting layer/material. In some implementations, the molding compound is a non-conducting material, such as an epoxy, which can be formed (applied, etc.) using a transfer molding process or a compression molding process. In some implementations, the molding compound can include a separate plastic housing that is included in the semiconductor device assembly.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth. In various examples, gold, aluminum, silver, and combinations thereof can be used as materials for electrical connections.

In some implementations, one or more semiconductor die associated with the implementations described herein can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a module (e.g., a package including a semiconductor device) can be included in another module. The module can be referred to as a package. For example, one or more modules can be one or more sub modules included within another module. In other words, a first module can be included as a sub module within a second module.

In some implementations, a spacer material can be an epoxy, a silicone adhesive, a conductive material, a non-conductive material, an organic material, a semiconductor material, a metal alloy, a metal foam, a phase change material, etc.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Silicon Carbide (SiC), Gallium Arsenide (GaAs), Gallium Nitride (GaN), other wide band gap materials, and so forth.

While certain features of the described implementations have been illustrated as described herein, many modifications, substitutions, changes and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. An apparatus comprising:
a substrate; and
a semiconductor die sintered to the substrate using an assist film, the semiconductor die having a surface including substantially planar portion and at least one projection extending from the substantially planar portion in a direction orthogonal to the surface, wherein the semiconductor die is sintered to the substrate by:
disposing the semiconductor die on a sintering material applied to the substrate;
disposing the assist film on the surface of the semiconductor die, the assist film including at least one spacer, wherein the assist film is disposed such that the at least one spacer contacts the substantially planar portion;
applying pressure to the assist film; and
applying thermal energy at a sintering temperature to sinter the semiconductor die to the substrate.

2. The apparatus of claim 1, wherein the at least one spacer defines at least one recess in the assist film, wherein the assist film is disposed such that the at least one projection is disposed within the at least one recess.

3. The apparatus of claim 2, wherein the at least one spacer defines a pattern of recesses.

4. The apparatus of claim 1, wherein the assist film includes a plurality of spacers disposed on the surface of the semiconductor die using an adhesive material, the plurality of spacers being disconnected.

5. The apparatus of claim 1, wherein the at least one projection includes a photosensitive polyimide layer.

6. The apparatus of claim 1, wherein the assist film includes at least one of:
a polymer; or
a polyimide.

7. The apparatus of claim 1, wherein the substrate includes one of:
a die attach paddle of a leadframe;
a metal layer of a direct bonded metal substrate; or
a heat dissipation device.

8. A method for producing a semiconductor device assembly, the method comprising:
disposing a semiconductor die on a sintering material applied to a die attach surface, the semiconductor die having a surface including substantially planar portion and at least one projection extending from the substantially planar portion in a direction orthogonal to the surface;
disposing a film on the surface of the semiconductor die, the film including at least one spacer, wherein the film is disposed such that the at least one spacer contacts the substantially planar portion;
applying pressure to the film; and
applying thermal energy at a sintering temperature to sinter the semiconductor die to the die attach surface.

9. The method of claim 8, wherein the at least one spacer defines at least one recess in the film, wherein the film is disposed such that the at least one projection is disposed within the at least one recess.

10. The method of claim 9, wherein the at least one spacer defines a pattern of recesses.

11. The method of claim 8, wherein disposing the film having the at least one spacer includes disposing a plurality of spacers on the surface of the semiconductor die using an adhesive material, the plurality of spacers being disconnected.

12. The method of claim 8, wherein the at least one projection includes a photosensitive polyimide layer.

13. The method of claim 8, wherein the film includes at least one of:
a polymer; or
a polyimide.

14. The method of claim 8, wherein the sintering material is one of a sintering paste or a sintering film.

15. The method of claim 8, wherein the sintering material is one of:
a silver sintering material; or
a copper sintering material.

16. The method of claim 8, wherein the die attach surface is one of:
a surface of a die attach paddle of a leadframe;
a surface of a metal layer of a direct bonded metal substrate; or
a surface of a heat dissipation device.

17. A method for producing a semiconductor device assembly, the method comprising:
disposing a semiconductor die on a die attach surface, the semiconductor die having a surface including substantially planar portion and at least one projection extending from the substantially planar portion in a direction orthogonal to the surface;
disposing a sinter film on the surface of the semiconductor die, the sinter film including at least one spacer extending from the substantially planar portion in a direction orthogonal to the surface;
disposing a conductor on the sinter film;
applying pressure to the conductor; and
applying thermal energy at a sintering temperature to sinter the conductor to the semiconductor die.

18. The method of claim 17 further comprising:
applying sintering material to the die attach surface; and
disposing the semiconductor die on the sintering material, wherein the semiconductor die is sintered to the die attach surface contemporaneous with sintering the conductor to the semiconductor die.

19. The method of claim 17, wherein the at least one projection includes at least one of:
a portion of a metallization layer; or
a photosensitive polyimide layer.

20. The method of claim 17, wherein the conductor is a conductive clip.

21. The method of claim 17, wherein the die attach surface is one of:
a surface of a die attach paddle of a leadframe;
a surface of a metal layer of a direct bonded metal substrate; or
a surface of a heat dissipation device.

22. A method for producing a semiconductor device assembly, the method comprising:
disposing a semiconductor die on sintering material applied to a die attach surface, the semiconductor die having a surface including substantially planar portion and at least one projection extending from the substantially planar portion in a direction orthogonal to the surface;
disposing a film on the surface of the semiconductor die such that the film covers the at least one projection;
planarizing the film;
applying pressure to the film; and
applying thermal energy at a sintering temperature to sinter the semiconductor die to the die attach surface.

23. The method of claim 22, wherein the film is photosensitive polyimide layer.
